(19) United States
(12) Patent Application Publication
(10) Pub. No.: US 2026/0305497 A1
(43) Pub. Date: Oct. 1, 2026

(54) MEMORY-ONLY CUBES AND METHODS OF FORMING THE SAME

(71) Applicant: Micron Technology, Inc., Boise, ID (US)

(72) Inventor: Wei Zhou, Boise, ID (US)

(21) Appl. No.: 19/561,502

(22) Filed: Mar. 10, 2026

Related U.S. Application Data
(60) Provisional application No. 63/781,960, filed on Apr. 1, 2025.

(51) Int. Cl. H10W 90/00; H10W 72/00; H10B 80/00; H10W 90/26

(52) U.S. Cl. CPC H10W 90/732; H10W 72/01304; H10W 72/01333; H10W 72/07332; H10W 72/856; H10W 90/722; H10W 90/724; H10W 90/734; H10B 80/00; H10W 90/26

(57) ABSTRACT

Memory-only cubes and methods of forming the same are disclosed herein. In one embodiment, a semiconductor device includes (i) a dielectric layer comprising a spin-on dielectric material, and (ii) a stack of semiconductor dies disposed on the dielectric layer. The spin-on dielectric material can be a photoimageable dielectric material. A first semiconductor die of the stack can be bonded to the dielectric layer, such as using a thermocompression bond or a hybrid bond. One or more interconnect structures can be formed in the dielectric layer, and external contacts can be disposed at a side of the dielectric layer opposite the stack of semiconductor dies. The one or more interconnect structures can extend through the dielectric layer and electrically couple the first semiconductor die to the external contacts.

### CROSS-REFERENCE TO RELATED APPLICATIONS

The present application claims priority to U.S. Provisional Patent Application No. 63/781,960, filed Apr. 1, 2025, the disclosure of which is incorporated herein by reference in its entirety.

### TECHNICAL FIELD

The present disclosure relates generally to semiconductor devices. For example, several embodiments of the present technology described in detail below are directed to memory cubes that are formed without use of an interface wafer or die, and to methods of assembling the same.

### BACKGROUND

Semiconductor devices are commonly arranged in vertical stacks. For example, memory cubes, particularly in the context of high-bandwidth memory (HBM) devices, typically involve the integration of multiple memory dies stacked vertically to form compact, high-performance memory modules. These memory cubes are often used in conjunction with a host device within system-in-package (SiP) configurations to enhance data processing speeds and reduce physical space requirements.

Memory cubes traditionally utilize interface dies, often logic dies, that facilitate communication between the memory dies and external devices, such as host devices. The interface dies typically contain through-silicon vias (TSVs) and other interconnect structures that provide necessary pathways for electrical signals between the stacked memory dies and the host devices or other external circuitry. Use of interface dies, however, can introduce additional complexity and cost in the manufacturing process, and can limit reducing the overall heights of the memory cubes.

### BRIEF DESCRIPTION OF THE DRAWINGS

Many aspects of the present disclosure can be better understood with reference to the following drawings. The components in the drawings are not necessarily to scale. Instead, emphasis is placed on illustrating clearly the principles of the present disclosure. The drawings should not be taken to limit the disclosure to the specific embodiments shown, but are provided for explanation and understanding.

FIG. 1 illustrates a cross-sectional side view of a semiconductor device configured in accordance with various embodiments of the present technology.

FIG. 2 illustrates a cross-sectional side view of a system-in-package (SiP) device that implements a semiconductor device configured in accordance with various embodiments of the present technology.

FIG. 3 illustrates a cross-sectional side view of another system-in-package that implements a semiconductor device configured in accordance with various embodiments of the present technology.

FIG. 4 is a flow diagram illustrating a method of manufacturing a semiconductor device in accordance with various embodiments of the present technology.

FIG. 5A illustrates a cross-sectional side view of a temporary carrier substrate configured in accordance with various embodiments of the present technology.

FIGS. 5B-5D illustrate cross-sectional side views of a semiconductor device at various stages of manufacturing in accordance with various embodiments of the present technology.

FIG. 6 illustrates a cross-sectional side view of a temporary carrier substrate configured in accordance with various embodiments of the present technology.

FIG. 7 illustrates a cross-sectional side view of a temporary carrier substrate configured in accordance with various embodiments of the present technology.

FIG. 8 illustrates a block diagram of a device assembly within a system configured in accordance with various embodiments of the present technology.

### DETAILED DESCRIPTION

The present technology relates generally to semiconductor devices (e.g., memory cubes) that are formed without interface dies or interface wafers. For example, several embodiments of the present technology described in greater detail below are directed to memory cubes that include stacks of memory dies positioned on or over dielectric layers. Vias and/or other interconnect structures can be formed in the dielectric layer to facilitate communicably coupling the memory dies to host devices and other external circuitry. Thus, the dielectric layers can be used in lieu of interface dies or wafers. In some embodiments, the dielectric layers can be formed of a spin-on dielectric, or other suitable materials. It is expected that such memory cubes and methods of assembling the same can result in thinner and/or more cost-effective memory modules that perform similarly to traditional high-bandwidth memory.

In the following description, specific details are set forth to provide a thorough understanding of aspects of the present technology. One skilled in the relevant art will recognize, however, that the systems, devices, and techniques described herein can be practiced without one or more of the specific details set forth herein, or with other methods, components, materials, etc. For example, although primarily described below in the context of memory cubes that implements stacks of dynamic random-access memory (DRAM) dies, the present technology is not so limited. Other embodiments of the present technology can be directed to memory cubes that implement stacks of other forms of volatile memory dies, stacks of non-volatile memory dies (e.g., NOT-AND (NAND) memory dies), and/or stacks that include both volatile and non-volatile memory dies.

Reference throughout this specification to an “example” or an “embodiment” means that a particular feature, structure, or characteristic described in connection with the example or embodiment is included in at least one example or embodiment of the present technology. Thus, use of the phrases “for example,” “as an example,” or “an embodiment” herein are not necessarily all referring to the same example or embodiment and are not necessarily limited to the specific example or embodiment discussed. Furthermore, features, structures, or characteristics of the present technology described herein may be combined in any suitable manner to provide further examples or embodiments of the present technology.

Spatially relative terms (e.g., “beneath,” “below,” “over,” “under,” “above,” “upper,” “top,” “bottom,” “left,” “right,” “center,” “middle,” and the like) may be used herein for ease of description to describe one element’s or feature’s relationship relative to one or more other elements or features as illustrated in the figures. It will be understood that the spatially relative terms are intended to encompass different orientations of a device or system in use or operation, in addition to the orientation depicted in the figures. For example, if a device or system illustrated in the figures is rotated, turned, or flipped about a horizontal axis, elements or features described as “below” or “beneath” or “under” one or more other elements or features may then be oriented “above” the one or more other elements or features. Thus, the exemplary terms “below” and “under” are non-limiting and can encompass both an orientation of above and below. The device or system may additionally, or alternatively, be otherwise oriented (e.g., rotated ninety degrees about a vertical axis, or at other orientations) than illustrated in the figures, and the spatially relative descriptors used herein are interpreted accordingly. In addition, it will also be understood that when an element is referred to as being “between” two other elements, it can be the only element between the two other elements, or one or more intervening elements may also be present.

A. Selected Embodiments of Memory-Only Cubes, and Associated Systems, Devices, and Methods

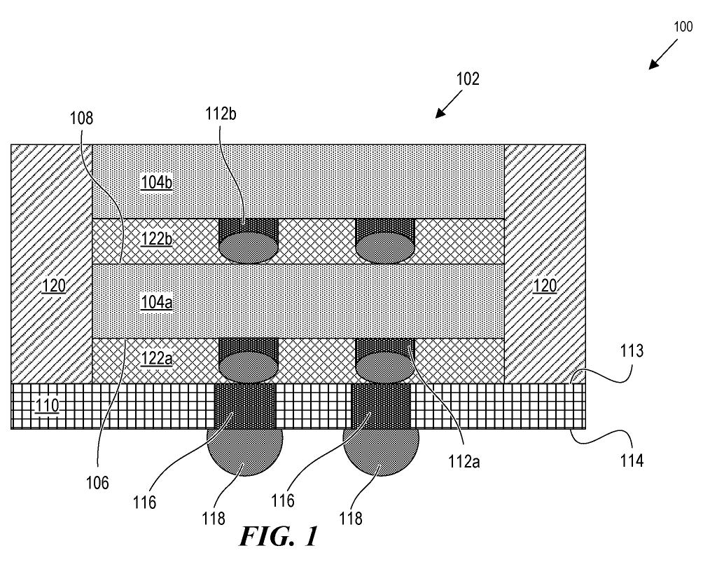

FIG. 1 illustrates a cross-sectional side view of a semiconductor device 100 configured in accordance with various embodiments of the present technology. As shown, the semiconductor device 100 includes a stack 102 of semiconductor dies 104 (identified individually in FIG. 1 as semiconductor die 104a and semiconductor die 104b), a dielectric layer 110, dielectric layers 122 (identified individually in FIG. 1 as dielectric layer 122a and dielectric layer 122b), and a molding compound 120.

In some embodiments, the semiconductor dies 104 can be memory dies. For example, all or a subset of the semiconductor dies 104 can be volatile memory dies. As a specific example, the semiconductor dies 104a and 104b can be DRAM memory dies. In other embodiments, one or more of the semiconductor dies 104 can be non-volatile memory dies. In embodiments in which all or a subset of the semiconductor dies are memory dies, the semiconductor device 100 can be referred to as a "memory cube" or "memory module." Although shown with only two semiconductor dies 104 in FIG. 1, semiconductor devices configured in accordance with other embodiments of the present technology can include more than two semiconductor dies arranged in a stack and/or more than one stack of semiconductor dies.

The semiconductor dies 104 can be arranged front-to-back, back-to-front, front-to-front, and/or back-to-back in the stack 102. For example, the semiconductor dies 104a can include a first side 106 and a second side 108 opposite the first side 106. In some embodiments, the first side 106 can be a front side of the semiconductor die 104a, and the second side 108 can be a back side of the semiconductor die 104a. In these embodiments, a front side or a back side of the semiconductor die 104b can be attached to the second side 108 of the semiconductor die 104a. In other embodiments, the first side 106 can be a back side of the semiconductor die 104a, and the second side 108 can be a back side of the semiconductor die 104a. In these embodiments, a front side or a back side of the semiconductor die 104b can be attached to the second side 108 of the semiconductor die 104a.

In the illustrated embodiment, the semiconductor die 104b is bonded to the semiconductor die 104a via a dielectric layer 122b and one or more interconnect structures 112b. As a specific example, the semiconductor die 104b can be bonded to the semiconductor die 104a using thermocompression bonding (TCB) and/or a hybrid bond. As a result, the semiconductor device 100 can include a bondline between the semiconductor die 104a and the semiconductor die 104b. The dielectric layer 122b can be a non-conductive film or a molded underfill. The interconnect structures 112b can include bond pads, solder balls, and the like. Additionally, or alternatively, the interconnect structures 112b can be used to communicably and/or electrically couple (a) the semiconductor die 104b to (b) the semiconductor die 104a and/or the dielectric layer 110. In other embodiments, the semiconductor die 104b can be bonded to the semiconductor die 104a using another suitable bonding technique and/or another suitable bond type (e.g., a fusion bond).

The dielectric layer 110 can be formed of any suitable dielectric material. For example, the dielectric layer 110 can be a spin-on dielectric (SOD) material, such as an oxide or a polymer-based inorganic compound. As another example, the dielectric layer 110 can be a dry-film photoimageable dielectric (PED) material.

As shown, the dielectric layer 110 includes a first side 113 and a second side 114 opposite the first side 113. The first side 113 can be a top side of the dielectric layer 110 and the second side 114 can be a bottom side of the dielectric layer 110. In some embodiments, the dielectric layer 110 can be relatively thin (e.g., in comparison to an interface die), having a thickness on the order of a few microns, such as 3-7 microns (measured in a direction extending generally from the second side 114 toward the first side 113).

In the illustrated embodiment, the stack 102 of the semiconductor dies 104 is positioned on or over the dielectric layer 110, such as on the first side 113 of the dielectric layer 110. More specifically, the semiconductor die 104a of the stack 102 (representing a bottommost semiconductor die of the stack 102) can be bonded to the dielectric layer 110 via a dielectric layer 122a and one or more interconnect structures 112a. The semiconductor die 104a can be bonded to the dielectric layer 110 using thermocompression bonding (TCB) and/or a hybrid bond. As a result, the semiconductor device 100 can include a bondline between the semiconductor die 104a and the dielectric layer 110. The dielectric layer 122a can be a non-conductive film or a molded underfill. The interconnect structures 112a can include bond pads, solder balls, and the like. Additionally, or alternatively, the interconnect structures 112a can be used to communicably and/or electrically couple (a) the semiconductor die 104a to (b) the dielectric layer 110. In other embodiments, the semiconductor die 104a can be bonded to the dielectric layer 110 using another suitable bonding technique and/or another suitable bond type (e.g., a fusion bond).

As shown, the dielectric layer 110 can include one or more interconnect structures 116 formed therein. The one or more interconnect structures 116 can include vias, traces, bond pads, under bump metallurgy, etc. In some embodiments, the interconnect structures 116 extend through the dielectric layer 110 (e.g., from the second side 114 to the first side 113). In these and other embodiments, interconnect structures 116 can form a redistribution layer (RDL). As shown, external contacts 118 (e.g., pillars) can be formed on one or more of the interconnect structures 116 at the second side 114 of the dielectric layer 110 opposite the semiconductor die 104a. The external contacts 118 can be used to communicably and/or electrically couple the semiconductor dies 104 to a host device, external circuitry, or a power supply. In some embodiments, such as embodiments in which the semiconductor device 100 does not implement redistribution layers within the dielectric layer 110, a pitch of the interconnect structures 116 and/or the external contacts 118 can correspond to a pitch of the interconnect structures 112a and/or corresponding bond pads/electrical contacts on the semiconductor die 104a. In other embodiments, such as embodiments in which the semiconductor device 100 implements a redistribution layer within the dielectric layer 110, a pitch of the interconnect structures 116 and/or the external contacts 118 can be relaxed/larger than a pitch of the interconnect structures 112a and/or corresponding bond pads/electrical contacts on the semiconductor die 104a, such as to match JEDEC standards. In some embodiments, an interconnect structure of the interconnect structures 116 can extend through the dielectric layer 110 from an external contact of the one or more external contacts 118 to the first side 113 of the dielectric layer 110 layer and couple the external contact to the semiconductor die stack 102. For example, the one or more of the interconnect structures 116 can couple one or more of the external contacts 118 to a bottom semiconductor die, such as semiconductor die 104a. The interconnect structures 116 and/or the external contacts 118 can be formed of nickel, gold, copper, tungsten, or another suitable material.

The molding compound 120 can be disposed over the stack 102 of semiconductor dies 104. In some embodiments, the semiconductor die 104b (representing a topmost semiconductor die of the stack 102) can be exposed at the top of the semiconductor device 100, such as by backgrinding the molding compound 120 after it is used to encapsulate the stack 102. In other embodiments, the molding compound 120 can encapsulate, cover, and/or extend over all or a portion of the semiconductor die 104b at the top of the semiconductor device 100 (e.g., such that the semiconductor dies 104 are surrounded by the molding compound along three or more sides of the semiconductor device 100). As shown, the molding compound 120 can additionally be positioned over the dielectric layer 110. For example, the molding compound 120 can be disposed (e.g., directly) on the first side 113 of the dielectric layer 110 and disposed about the sides of the stack 102 of semiconductor dies 104.

In some cases, the dielectric layer 110 may emulate an interface or logic die of a high-bandwidth memory device (HBM), which may allow the semiconductor device 100 to emulate a high-bandwidth memory (HBM) device without using an interface or logic die.

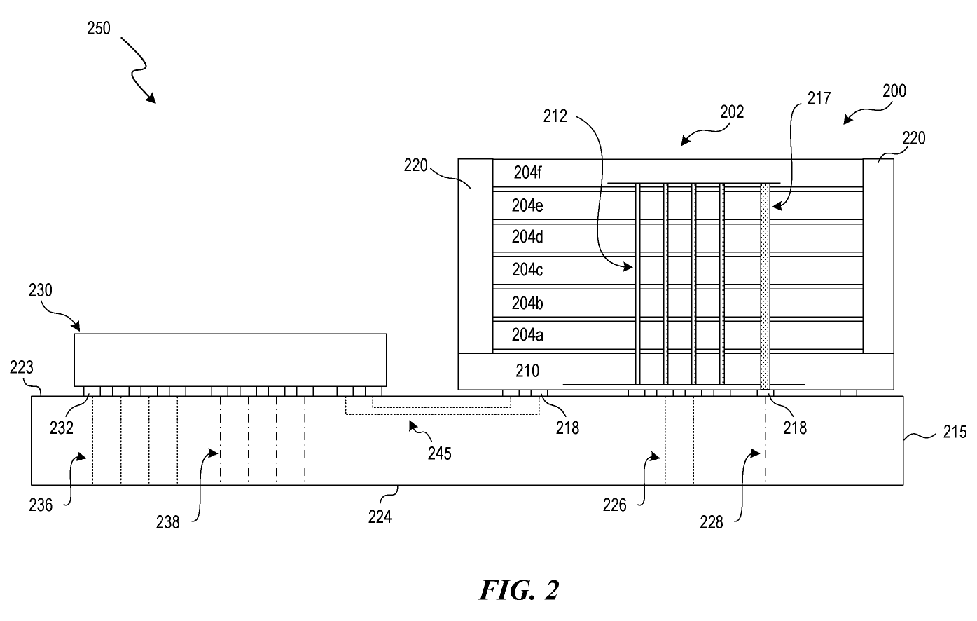

FIG. 2 is a partially schematic cross-sectional diagram of a system-in-package (SiP) device 250 configured in accordance with various embodiments of the present technology. As shown, the SiP device 250 includes an interposer 215 having a first surface 223 and a second surface 224 opposite the first surface 223. The interposer 215 can be a silicon interposer, an organic interposer, an inorganic interposer, and/or any other suitable base substrate. The SiP device 250 further includes a semiconductor device 200 and a host device 230 disposed on the first surface 223 of the interposer 215. The semiconductor device 200 is coupled to the interposer 215 via a plurality of contacts 218, and the host device 230 is coupled to the interposer 215 via a plurality of contacts 232. The contacts 218, 232 can be solder structures (e.g., solder balls), metal-metal bonds, and/or any other suitable conductive structures that mechanically and electrically couple the interposer 215 to the host device 230 and the semiconductor device 200.

The semiconductor device 200 can be generally similar to the semiconductor device 100 of FIG. 1 described in detail above. Accordingly, similar reference numbers are used across FIGS. 1 and 2 to denote identical or at least generally similar components, and a detailed description of the semiconductor device 200 is largely omitted here for the sake of brevity in light of the detailed description provided above. In the illustrated embodiment, the semiconductor device 200 includes a stack 202 of semiconductor dies 204 (identified individually in FIG. 2 as semiconductor dies 204a-204f) disposed on or over a dielectric layer 210 (e.g., an SOD layer) and a molding compound 220 disposed on the dielectric layer 210 and/or disposed about the stack 202.

The semiconductor dies 204a-204f are each communicably and/or electrically coupled to the dielectric layer 210 via one or more signal interconnect structures 212 (e.g., through silicon vias (TSVs) and/or other conductive structures) and one or more power interconnect structures 217 (e.g., TSVs and/or other conductive structures). The semiconductor dies 204a-204f can further be coupled to circuitry external the semiconductor device 200. For example, the semiconductor dies 204 can be coupled to the host device 230 via interconnect structures in the dielectric layer 210, the contacts 218, and communication channels 245 (sometimes referred to as a SiP bus) formed in the interposer 215. The communication channels 245 can include one or more route lines (two illustrated schematically in FIG. 2) formed into (or on) the interposer 215. Additionally, or alternatively, the semiconductor device 200 can be coupled to an external component (e.g., a PCB the interposer 215 is integrated with, an external controller, and/or the like), such as via interconnect structures in the dielectric layer 210, the contacts 218, signal interconnect structures 226 (e.g., TSVs and/or other conductive structures) formed in the interposer 215, and/or power interconnect structures 228 (e.g., TSVs and/or other conductive structures) formed in the interposer 215. In some embodiments, one or more signal interconnect structures 226 can be referred to as direct access interconnect structures, can be used to communicate signals (e.g., data, control signals, processing commands, and/or the like) between an external component and the dielectric layer 210, and/or can extend between the first surface 223 and the second surface 224 of the interposer 215. The power interconnect structures 228 can provide electrical power to the semiconductor device 200 from an external power source.

In some embodiments, the SiP device 250 can include an interface or logic die positioned on the first surface 223 of the interposer 215 between the interposer 215 and the semiconductor device 200 (e.g., between the interposer 215 and the dielectric layer 210). The interface or logic die can provide additional processing capabilities, memory control functions, or other logic operations to support the semiconductor device 200. The interface or logic die can allow the semiconductor device 200 to emulate a HBM device, for example, in embodiments in which the dielectric layer 210 is not configured to emulate an interface or logic die and/or is not configured to be used in lieu of an interface or logic die. The interface or logic die can be communicably and/or electrically coupled to the semiconductor device 200 through interconnect structures in the interface or logic die, contacts on the upper surface of the interface or logic die, and corresponding contacts on the lower surface of the semiconductor device 200, similar to contacts 218. Additionally, or alternatively, the interface or logic die can be coupled to the host device 230 via communication channels 245 formed in the interposer 215. The semiconductor device 200 can be communicably and/or electrically coupled to the host device 230 through the interface or logic die through interconnect structures in the interface or logic die and/or communication channels 245 formed in the interposer 215.

The host device 230 can include a variety of components, such as a processing unit (e.g., CPU/GPU/TCU), one or more registers, one or more cache memories, and/or a variety of other components. In some embodiments, the host device 230 can be coupled to an external component (e.g., a PCB the interposer 215 is integrated with, an external controller, and/or the like) via the contacts 232, signal interconnect structures 236 (e.g., TSVs and/or other conductive structures) formed in the interposer 215, and/or power interconnect structures 238 (e.g., TSVs and/or other conductive structures) formed in the interposer 215. The signal interconnect structures 236 and/or the power interconnect structures 238 can extend between the first surface 223 and the second surface 224 of the interposer 215. Additionally, or alternatively, the signal interconnect structures 236 can communicate signals (e.g., data, control signals, processing commands, and/or the like) between the external component and the host device 230. The power interconnect structures 238 can provide electrical power to the host device 230 from an external power source.

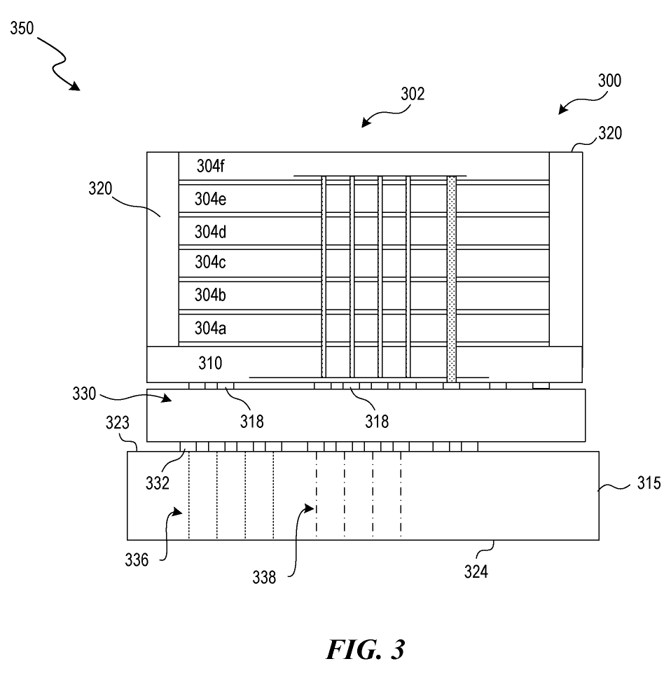

FIG. 3 illustrates a cross-sectional side view of another SiP device 350 configured in accordance with various embodiments of the present technology. The SiP device 350 is generally similar to the SiP device 250 of FIG. 2 described in detail above. Accordingly, similar reference numbers are used across FIGS. 2 and 3 to denote identical or at least generally similar components, and a detailed description of the SiP device 350 is largely omitted herein for the sake of brevity in light of the description of the SiP device 250 of FIG. 2 provided above.

As shown in FIG. 3, the SiP device 350 includes an interposer 315 (e.g., a silicon interposer, an organic interposer, an inorganic interposer, and/or any other suitable base substrate) having a first side 323 and a second side 324 opposite the first side 323. The SiP device 350 further includes a host device 330 and a semiconductor device 300 disposed on or over the first side 323 of the interposer 315. In contrast with the semiconductor device 200 of the SiP device 250 of FIG. 2, the semiconductor device 300 of the SiP device 350 of FIG. 3 is disposed on or over the host device 330. For example, the host device 330 can be coupled to the interposer 315 via a plurality of contacts 332, and the semiconductor device 300 is carried by the host device 330 and is coupled to the host device 330 via a plurality of contacts 318. The contacts 318, 332 can be solder structures (e.g., solder balls), metal-metal bonds, and/or any other suitable conductive structure.

The interposer 315 can include a plurality of signal interconnect structures 336 and a plurality of power interconnect structures 338. The signal interconnect structures 336 and/or the power interconnect structures 338 can include TSVs or other conductive structures, can extend between the first side 323 and the second side 324 of the interposer 315, and/or can be configured to transmit signals and/or power between an external component and the host device 330.

The semiconductor device 300 can be an example of the semiconductor device 100 of FIG. 1, the semiconductor device 200 of FIG. 2, or another semiconductor device configured in accordance with various embodiments of the present technology. Consistent with the discussion above, the semiconductor device 300 includes a plurality of semiconductor dies 304 (identified individually in FIG. 3 as semiconductor dies 304a-304f) arranged in a stack 302 and disposed on or over a dielectric layer 310 (e.g., an SOD layer). The semiconductor device 300 can further include a molding compound 320 disposed on the dielectric layer 310 and/or disposed about the stack 302.

In some embodiments, the SiP device 350 can include an interface or logic die positioned on the host device 330 and disposed between the host device 330 and the semiconductor device 300. The interface or logic die can be coupled to the host device 330 via a plurality of contacts similar to contacts 318. The interface or logic die can provide additional processing capabilities, memory control functions, or other logic operations to support the semiconductor device 300. The interface or logic die can allow the semiconductor device 300 to emulate an HBM device, for example, in embodiments in which the dielectric layer 310 is not configured to emulate an interface or logic die and/or is not configured to be used in lieu of an interface or logic die.

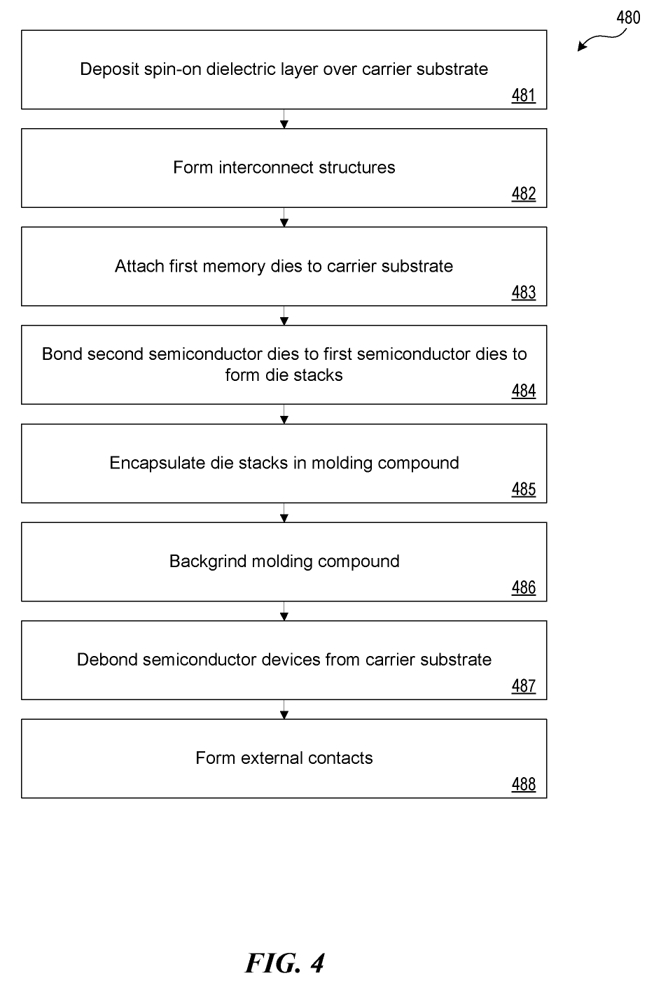

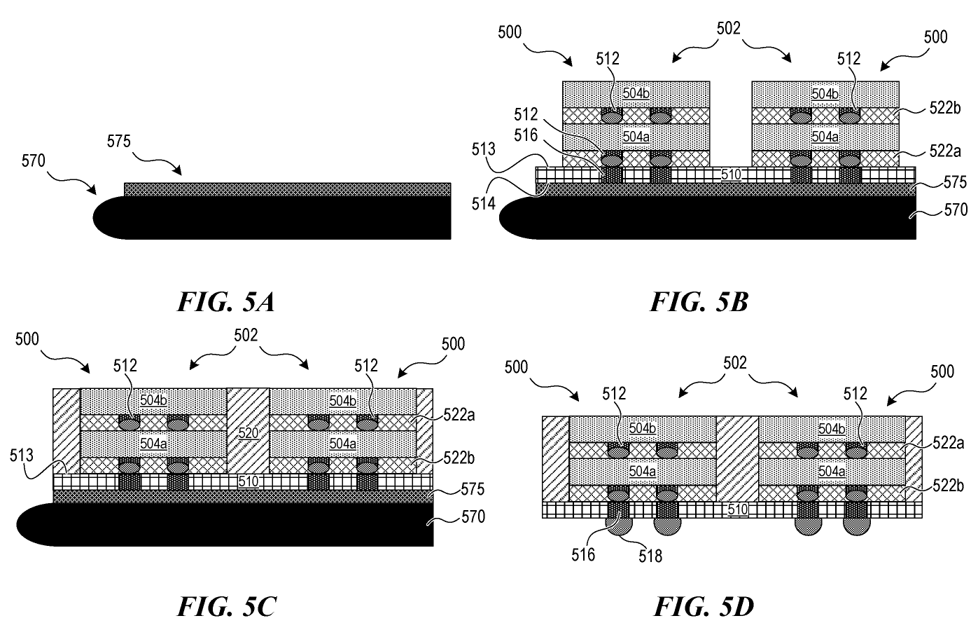

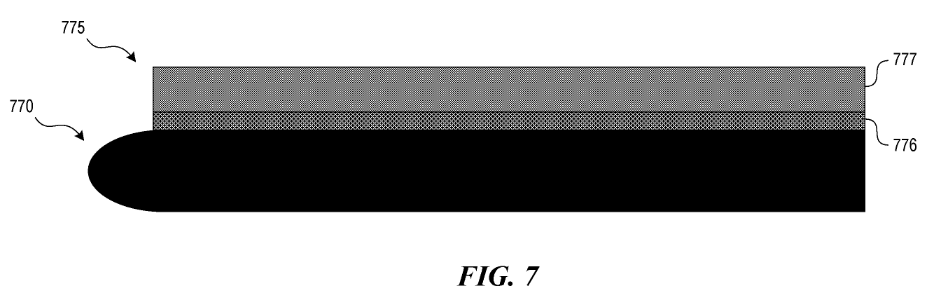

FIG. 4 is a flow diagram illustrating a method 480 of manufacturing a semiconductor device in accordance with various embodiments of the present technology. The semiconductor device can be the semiconductor device 100 of FIG. 1, the semiconductor device 200 of FIG. 2, the semiconductor device 300 of FIG. 3, or another semiconductor device configured in accordance with various embodiments of the present technology. The method 480 is illustrated as a series of steps 481-488. All or a subset of one or more of the steps 481-488 can be executed in accordance with the description above and/or with the description that follows. Indeed, several of the steps 481-488 are described in detail below with reference to FIGS. 5A-7. FIGS. 5A, 6, and 7 illustrate cross-sectional side views of temporary carrier substrates 570, 670, and 770, respectively, configured in accordance with various embodiments of the present technology. FIGS. 5B-5D illustrate cross-sectional side views of a semiconductor device 500 at various stages of manufacturing in accordance with various FIG. 7 embodiments of the present technology.

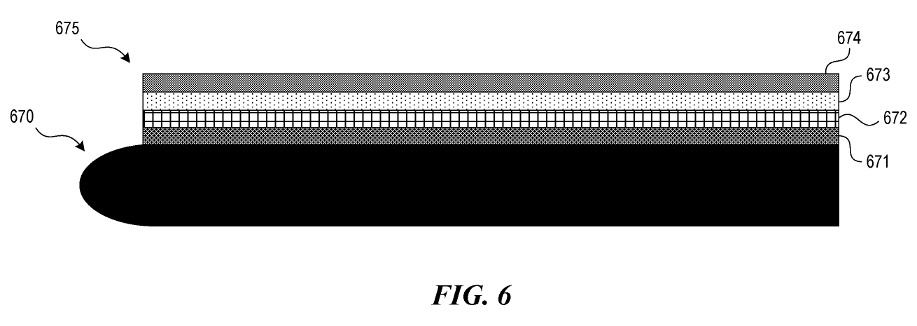

At step 481, the method 400 begins by depositing a dielectric layer over a carrier substrate. The dielectric layer can be a layer of spin-on dielectric or another suitable material. The carrier substrate can be a temporary carrier substrate, such as formed of silicon or glass. The carrier substrate can include a temporary layer disposed on or over the carrier substrate, and depositing the dielectric layer over the carrier substrate can include depositing the dielectric layer on or over the temporary layer. For example, referring to FIG. 5A, the carrier substrate 570 can include a temporary layer 575 disposed thereon. In some embodiments, the temporary layer 575 can be formed from a plurality of layers. Two examples are shown in FIGS. 6 and 7.

In the example illustrated in FIG. 6, a temporary layer 675 is disposed on the carrier substrate 670. The carrier substrate 670 can be formed of silicon, glass, or another suitable material. As shown, the temporary layer 675 includes a plurality of layers. More specifically, the temporary layer 675 can include an ablation layer 671 that is usable to debond structures from the carrier substrate 670, as described in greater detail below. The temporary layer 675 can further include a dielectric layer 672, a shielding layer 673, and a bonding layer 674. The shielding layer 673 can be used to shield the bonding layer 674 and/or structures attached to the bonding layer 674 from radiation emitted, for example, using an infrared laser through the carrier substrate 670 and onto the ablation layer 671 to ablate the dielectric layer 672 and debond the temporary layer 675 from the carrier substrate 670. Such a debonding process is commonly referred to as nano cleaving (e.g., EVG nano cleaving) and/or dielectric debonding. Any of the layers shown in FIG. 6, such as ablation layer 671, dielectric layer 672, shielding layer 673, and/or bonding layer 674, can include multiple films and/or multiple layers of material.

In the example illustrated in FIG. 7, a temporary layer 775 is disposed on the carrier substrate 770. The carrier substrate 770 can be formed of glass, silicon, or another suitable material. As shown, the temporary layer 775 includes a plurality of layers. More specifically, the temporary layer 775 includes (i) an ablation layer 776 that is usable to debond structures from the carrier substrate 770 and (ii) a bonding layer 777. Any of the layers shown in FIG. 7, such as the ablation layer 776 and/or the bonding layer 777, can include multiple films and/or multiple layers of material. The bonding layer 777 can be a high-temperature adhesive in some embodiments. In embodiments in which the carrier substrate 770 is formed of glass, the temporary layer 775 can be used to debond structures from the carrier substrate 770 using pulses of light. For example, the ablation layer 776 can be a light-absorbing layer. Continuing with this example, pulses of light can be emitted such that they propagate through the carrier substrate 770 and are absorbed by the ablation layer 776. As the ablation layer 776 absorbs the pulses of light, the ablation layer 776 can heat up and ablate the bonding layer 777, thereby enabling debonding of structures from the carrier substrate 770. Such a debonding process is commonly referred to as photonic debonding.

At step 482, the method 400 continues by forming interconnect structures. Forming the interconnect structures can include forming vias, traces, bond pads, under bump metallurgy, redistribution layers, etc. within the dielectric layer deposited at step 481 above. The interconnect structures can extend through the dielectric layer from a side of the dielectric layer opposite the carrier substrate to a side of the dielectric layer attached to the carrier substrate. Referring to FIG. 5B for the sake of clarity and example, the carrier substrate 570 from FIG. 5A is shown, with a dielectric layer 510 disposed thereon. The dielectric layer 510 can include interconnect structures 516 formed therein. The interconnect structures 516 can extend through the dielectric layer 510 from a first side 513 of the dielectric layer 510 opposite the carrier substrate 570 to a second side 514 attached to the carrier substrate 570.

In the event the dielectric layer is a photoimageable material, forming the interconnect structures can include irradiating the dielectric layer (e.g., using ultraviolet (UV) light) through a mask, etching or otherwise removing exposed portions of the dielectric layer, and filling the resulting recesses/cavities/trenches with conductive material. In other embodiments, forming the interconnect structures can include disposing a layer of photoimageable material over the dielectric layer at a side of the dielectric layer opposite the carrier substrate, irradiating the photoimageable material (e.g., using UV light) through a mask, etching or otherwise removing exposed portions of the photoimageable material, filling the resulting recesses/cavities/trenches with conductive material, and removing remaining portions of the photoimageable material.

At step 483, the method 400 continues by attaching first semiconductor dies to the carrier substrate. Attaching the first semiconductor dies to the carrier substrate can include attaching the first semiconductor dies to a side of the dielectric layer opposite the carrier substrate, such as using a thermocompression bond and/or a hybrid bond. Referring to FIG. 5B, two first semiconductor dies 504a are shown, each disposed on or over—and attached to—the dielectric layer 510. In the illustrated embodiment, the first semiconductor dies 504a are bonded to dielectric layer 510 via a dielectric layer 522a (e.g., a non-conductive film or a molded underfill) and interconnect structures 512 (e.g., bond pads, solder balls, and the like), such as by using thermocompression bonding and/or a hybrid bond (e.g., a chip-to-wafer thermocompression bond and/or a chip-to-wafer hybrid bond). Furthermore, each of the first semiconductor dies 504a can be attached to the carrier substrate 570 of FIG. 5A via the temporary layer 575 disposed on the carrier substrate 570. More specifically, each of the first semiconductor dies 504a can be attached to the carrier substrate 570 at a side of the dielectric layer 510 opposite the carrier substrate 570, wherein the temporary layer 575 is disposed between the dielectric layer 510 and the carrier substrate 570. The first semiconductor dies can be memory dies, such as DRAM dies. The first semiconductor dies can be configured to serve as bottommost semiconductor dies in stacks of semiconductor dies.

At step 484, the method 400 continues by bonding one or more second semiconductor dies to each of the first semiconductor dies to form die stacks. Bonding the one or more second semiconductor dies to each of the first semiconductor dies can include bonding the one or more second semiconductor dies to each of the first semiconductor dies at a side of the first semiconductor dies opposite the dielectric layer, such as using thermocompression bonding and/or hybrid bonds (e.g., chip-to-chip thermocompression bonding and/or chip-to-chip hybrid bonds).

Referring again to FIG. 5B for the sake of clarity and example, a second semiconductor die 504b can be bonded to each of the first semiconductor dies 504a on a side of the first semiconductor dies 504a opposite the dielectric layer 510 to form two die stacks 502. In the illustrated embodiment, the second semiconductor dies 504b are bonded to corresponding first semiconductor dies 504a via a dielectric layer 522b (e.g., a non-conductive film or a molded underfill) and interconnect structures 512 (e.g., bond pads, solder balls, and the like), such as using thermocompression bonding and/or a hybrid bond (e.g., a chip-to-chip hybrid bond).

At step 485, the method 400 continues by encapsulating the die stacks in a molding compound. Encapsulating the die stacks can include applying molding compound to at least partially fill in gaps or spaces between adjacent die stacks/semiconductor devices arranged on the carrier substrate. Encapsulating the die stacks can include disposing molding compound on or over die stacks. Referring to FIG. 5C for the sake of clarity and example, a molding compound 520 is used to fill in gaps between adjacent die stacks 502 of adjacent semiconductor devices 500. As shown, the molding is disposed about each of the die stacks 502, extending along the full heights of the die stacks 502. In some embodiments, the molding compound 520 is disposed across the top surfaces of each of the second semiconductor dies 504b (representing the topmost semiconductor dies) in each of the die stacks 502. In the illustrated embodiment, the molding material is deposited in the gaps such that the molding material is (i) positioned on or over the first side 513 of the dielectric layer 510 and (ii) about the die stacks 502.

At step 487, the method 400 continues by backgrinding the molding compound. Backgrinding the molding compound can include removing excess portions of the molding compound disposed above the topmost semiconductor die of each die stack. In some embodiments, backgrinding the molding compound can include backgrinding the molding compound until a top surface of the topmost semiconductor die in the die stacks is exposed.

Referring to FIG. 5C for the sake of clarity and example, a molding compound 520 was previously disposed over each of the die stacks 502. In turn, excess molding compound 520 disposed above the second semiconductor dies 504b (representing the topmost semiconductor dies in each of the die stacks 502) has been removed via backgrinding. In the illustrated embodiment, excess molding compound 520 has been removed via backgrinding such that a top surface of the second semiconductor dies 504b of each of the die stacks 502 are exposed at the top of the semiconductor devices 500. As a result, the molding compound 520 is positioned at only locations that are laterally disposed with respect to die stacks 502, such as within gaps between adjacent die stacks 502. In other embodiments, the backgrinding process can conclude without removing all of the molding compound 520 disposed on or over the second semiconductor dies 504b. In such embodiments, finalized semiconductor devices 500 can include molding compound 520 disposed on or over at least a portion of the top surfaces of the second semiconductor dies 504b.

At step 487, the method 400 continues by debonding the semiconductor devices from the carrier substrate. Debonding the semiconductor devices can include separating the semiconductor devices from the carrier substrate at the temporary layer. For example, in embodiments in which the carrier substrate is formed of silicon, debonding the semiconductor devices can include debonding semiconductor devices by ablating one or more layers (e.g., an ablation layer and/or a dielectric layer) of the temporary layer through the carrier substrate and using a laser (e.g., an infrared laser), such as while shielding (e.g., using a shielding layer of the temporary layer) the semiconductor devices from radiation emitted by the laser. As another example, in embodiments in which the carrier substrate is formed of glass, debonding the semiconductor devices can include debonding the semiconductor devices by ablating one or more layers (e.g., a high-temperature adhesive layer) of the temporary layer, such as by emitting pulses of light through the carrier substrate and onto a light-absorbing ablation layer of the temporary layer. As still another example, debonding the semiconductor devices can include separating the semiconductor devices from the carrier substrate via mechanical debonding (e.g., pulling the semiconductor devices away from and/or apart from the carrier substrate). Furthermore, temporary layers remaining on the semiconductor devices after debonding the carrier substrate can also be removed (e.g., removing a shielding or adhesive layer by mechanical debonding and/or grinding).

At step 488, the method 400 continues by forming external contacts. In some embodiments, some or all of the interconnect structures (e.g., the interconnect structures as described with respect to step 482) are formed after debonding. In some embodiments, forming the external contacts can include forming the external contacts as part of the process of forming the interconnect structures. In these and other embodiments, forming the external contacts can include forming the external contacts via pillar plating, such as using a pillar-last method.

Referring to FIG. 5D for the sake of clarity and example, the semiconductor devices 500 have been debonded from the carrier substrate 570 (FIG. 5C) at or proximate the interface between the dielectric layers 510 and the temporary layer 575 (FIG. 5C). In addition, interconnect structures 516 have been formed within the dielectric layers 510 (at step 482 above and/or at step 488), and external contacts 518 have been formed on the interconnect structures 516. In the illustrated embodiment, the interconnect structures 516 are vias that extend all the way through the dielectric layers 510 from the external contacts 518 to the first semiconductor dies 504a, and the external contacts 518 are pillars. As discussed in greater detail above, the interconnect structures 516 and the external contacts 518 can be used to communicably and/or electrically couple the first semiconductor die 504a and/or second semiconductor dies 504b of the respective die stack 502 to external circuitry/components and/or power supplies. Although not shown in FIG. 5D, the two semiconductor devices 500 can be singulated, such as (i) using a saw, a laser, or another suitable method, and/or (ii) at a location positioned within the gap between the two semiconductor devices 500.

Although the steps 481-488 of the method 480 of FIG. 4 are discussed and illustrated in a particular order, the method 480 is not so limited. In other embodiments, all or a subset of one or more of the steps 481-488 of the method 480 can be performed in a different order. For example, although interconnect structures are formed in the dielectric layer at step 482 of the method 480 shown in FIG. 4, all or a subset of the interconnect structures in the dielectric layer can be formed in the dielectric layer after debonding the semiconductor devices from the carrier substrate and/or before forming the external contacts at step 488. Thus, at least a portion of step 482 can be executed after step 487 and before step 488 in some embodiments. Moreover, a person of ordinary skill in the relevant art will recognize that the illustrated method 480 can be altered and still remain within these and other embodiments of the present technology. For example, all or a subset of one or more of the steps 481-488 of the method 480 illustrated in FIG. 4 can be omitted and/or repeated in some embodiments.

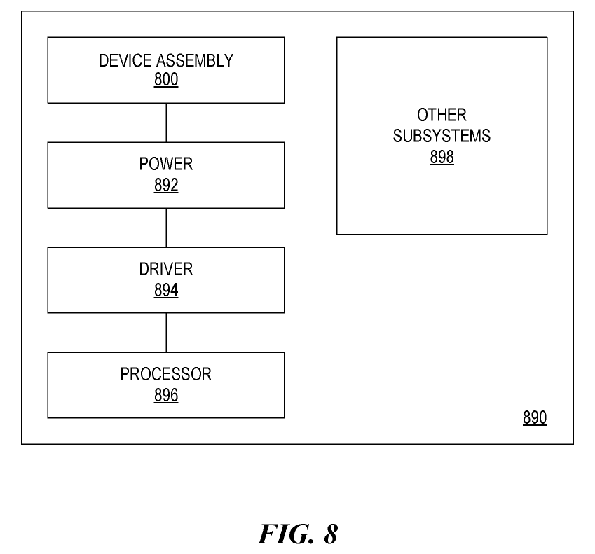

Any one of the semiconductor devices and semiconductor device assemblies described above with reference to FIGS. 1–7 can be incorporated into any of a myriad of larger and/or more complex systems, a representative example of which is system 890 shown schematically in FIG. 8. The system 890 can include a semiconductor device assembly 800 (e.g., similar to the semiconductor device 100, the semiconductor device 200, the semiconductor device 300, and/or the semiconductor device 500 described above with reference to FIGS. 1–3 and 5B-5D), a power source 892, a driver 894, a processor 896, and/or other subsystems or components 898. The semiconductor device assembly 800 can include features generally similar to those of the semiconductor devices described above with reference to FIGS. 1–7. The resulting system 890 can perform any of a wide variety of functions, such as memory storage, data processing, and/or other suitable functions. Accordingly, representative systems 890 can include, without limitation, hand-held devices (e.g., mobile phones, tablets, digital readers, and digital audio players), computers, vehicles, appliances, and other products. Components of the system 890 may be housed in a single unit or distributed over multiple, interconnected units (e.g., through a communications network). The components of the system 890 can also include remote devices and any of a wide variety of computer readable media.

### C. Conclusion

The above detailed descriptions of embodiments of the technology are not intended to be exhaustive or to limit the technology to the precise form disclosed above. Although specific embodiments of, and examples for, the technology are described above for illustrative purposes, various equivalent modifications are possible within the scope of the technology as those skilled in the relevant art will recognize. For example, although steps are presented in a given order above, alternative embodiments may perform steps in a different order. Furthermore, the various embodiments described herein may also be combined to provide further embodiments.

From the foregoing, it will be appreciated that specific embodiments of the technology have been described herein for purposes of illustration, but well-known structures and functions have not been shown or described in detail to avoid unnecessarily obscuring the description of the embodiments of the technology.

Where the context permits, singular or plural terms may also include the plural or singular term, respectively. In addition, unless the word “or” is expressly limited to mean only a single item exclusive from the other items in reference to a list of two or more items, then the use of “or” in such a list is to be interpreted as including (a) any single item in the list, (b) all of the items in the list, or (c) any combination of the items in the list. Furthermore, as used herein, the phrase “and/or” as in “A and/or B” refers to A alone, B alone, and both A and B. Additionally, the terms “comprising,” “including,” “having,” and “with” are used throughout to mean including at least the recited feature(s) such that any greater number of the same features and/or additional types of other features are not precluded. Moreover, as used herein, the phrases “based on,” “depends on,” “as a result of,” and “in response to” shall not be construed as a reference to a closed set of conditions. For example, an exemplary step that is described as “based on condition A” may be based on both condition A and condition B without departing from the scope of the present disclosure. In other words, as used herein, the phrase “based on” shall be construed in the same manner as the phrase “based at least in part on” or the phrase “based at least partially on.”

From the foregoing, it will also be appreciated that various modifications may be made without deviating from the disclosure or the technology. For example, one of ordinary skill in the art will understand that various components of the technology can be further divided into subcomponents, or that various components and functions of the technology may be combined and integrated. In addition, certain aspects of the technology described in the context of particular embodiments may also be combined or eliminated in other embodiments. Furthermore, although advantages associated with certain embodiments of the technology have been described in the context of those embodiments, other embodiments may also exhibit such advantages, and not all embodiments need necessarily exhibit such advantages to fall within the scope of the technology. Accordingly, the disclosure and associated technology can encompass other embodiments not expressly shown or described herein.

What is claimed is:

1. A semiconductor device, comprising:
a dielectric layer comprising a spin-on dielectric material;
a stack of semiconductor dies disposed on the dielectric layer, the stack comprising a first semiconductor die bonded to the dielectric layer;
one or more interconnect structures formed in the dielectric layer; and
external contacts disposed at a side of the dielectric layer opposite the stack of semiconductor dies, wherein the one or more interconnect structures extend through the dielectric layer and electrically couple the first semiconductor die to the external contacts.

2. The semiconductor device of claim 1, wherein the first semiconductor die is bonded to the dielectric layer via a thermocompression bond or a hybrid bond.

3. The semiconductor device of claim 1, wherein:
the first semiconductor die is coupled to the one or more interconnect structures via a plurality of interconnect structures; and
the external contacts are disposed at the side of the dielectric layer opposite the stack of semiconductor dies at a pitch corresponding to a pitch of the plurality of interconnect structures.

4. The semiconductor device of claim 1, wherein:
at least a subset of the one or more interconnect structures form a redistribution layer;
the first semiconductor die is coupled to the one or more interconnect structures via a plurality of interconnect structures; and
the external contacts are disposed at the side of the dielectric layer opposite the stack of semiconductor dies at a pitch that is larger than a pitch of the plurality of interconnect structures.

5. The semiconductor device of claim 1, further comprising a molding compound disposed over the dielectric layer and about the stack of semiconductor dies.

6. The semiconductor device of claim 5, wherein a topmost semiconductor die of the stack is exposed at a top of the semiconductor device.

7. The semiconductor device of claim 1, wherein the spin-on dielectric material is a dry-film photoimageable dielectric (PED) material.

8. The semiconductor device of claim 1, wherein the dielectric layer has a thickness between 3 microns and 7 microns.

9. The semiconductor device of claim 1, further comprising a non-conductive film of a molded underfill disposed between the first semiconductor die and the dielectric layer.

10. The semiconductor device of claim 1, wherein the stack includes a second semiconductor die stacked over the first semiconductor die using a non-conductive film or a molded underfill.

11. The semiconductor device of claim 1, wherein the stack includes a second semiconductor die bonded to the first semiconductor die via a thermocompression bond or a hybrid bond.

12. The semiconductor device of claim 1, wherein the stack of semiconductor dies comprises a plurality of dynamic random-access memory (DRAM) dies.

13. A method of manufacturing a semiconductor device, the method comprising:
depositing a spin-on dielectric layer over a carrier substrate;
forming interconnect structures in the spin-on dielectric layer;
bonding a first semiconductor die to the spin-on dielectric layer;
stacking one or more second semiconductor dies over the first semiconductor die to form a die stack; and
debonding the semiconductor device from the carrier substrate.

14. The method of claim 13, wherein bonding the first semiconductor die to the spin-on dielectric layer includes bonding the first semiconductor die to the spin-on dielectric layer using a thermocompression bond or a hybrid bond.

15. The method of claim 13, wherein forming the interconnect structures includes:
irradiating the spin-on dielectric layer through a mask;
etching exposed portions of the spin-on dielectric layer to form recesses; and
filling the recesses with conductive material.

16. The method of claim 13, further comprising disposing a molding compound on the spin-on dielectric layer and about the die stack.

17. The method of claim 13, wherein forming the interconnect structures comprises forming a redistribution layer within the spin-on dielectric layer.

18. The method of claim 13, further comprising forming external contacts at a side of the spin-on dielectric layer opposite the die stack and using a pillar-last method.

19. A system-in-package device, comprising:
a host device; and
a semiconductor device including:
a dielectric layer comprising a spin-on dielectric material,
a stack of semiconductor dies disposed on the dielectric layer, the stack comprising a first semiconductor die bonded to the dielectric layer,
interconnect structures formed in the dielectric layer, and
external contacts disposed at a side of the dielectric layer opposite the stack of semiconductor dies,
wherein the interconnect structures couple the first semiconductor die to the external contacts, and
wherein semiconductor dies of the stack are communicably coupled to the host device via one or more of the interconnect structures and one or more of the external contacts.

20. The system-in-package device of claim 19, wherein the first semiconductor die is bonded to the dielectric layer via a thermocompression bond or a hybrid bond.
